(19) United States
(12) Patent Application Publication
(10) Pub. No.: US 2007/0158662 A1
(43) Pub. Date: Jul. 12, 2007

(54) Two-dimensional photonic crystal LED

(75) Inventors: Dai Ohnishi, Kyoto-shi (JP); Susumu Noda, Kyoto-shi (JP)

Correspondence Address: OLIFF & BERRIDGE, PLC, P.O. BOX 19928, ALEXANDRIA, VA, 22320, US

(73) Assignees: KYOTO UNIVERSITY, KYOTO-SHI (JP); ROHM CO., LTD., KYOTO-SHI (JP)

(21) Appl. No.: 11/640,837

(22) Filed: Dec. 19, 2006

(30) Foreign Application Priority Data
Dec. 20, 2005 (JP) 2005-366117

(51) Int. Cl. H01L 33/00

(52) U.S. Cl. 257/79

(57) ABSTRACT

A two-dimensional photonic crystal LED composed of a p-type semiconductor cladding layer 12, an active layer 11 of light-emitting material, and an n-type semiconductor cladding layer 13 placed between a pair of electrodes, where air holes 16 penetrating through the layers 12, 11 and 13 and arranged periodically in the layers 12, 11 and 13 are provided. At least a part of the inner wall of the air holes 16 is oxidized 17 in either one or both of the p-type semiconductor cladding layer 12 and the n-type semiconductor cladding layer 13. The holes and electrons injected from the electrodes avoid the oxidized region 17 and enter the active layer 11 apart from the air holes 16, which minimizes the recombination (surface recombination) of the holes and electrons producing heat instead of light.

The present invention relates to a light emitting diode (LED) including a photonic crystal on the active layer or another layer.

### BACKGROUND OF THE INVENTION

Researches have been made to obtain an LED having a high light emitting efficiency, among which one including a two-dimensional photonic layer is a major candidate.

A photonic crystal is a body provided with an artificial periodic structure formed within a dielectric (matrix). The periodic structure is generally made by forming areas having a refractive index different from that of the matrix appearing periodically in the matrix. Each of the areas can be made by embedding a small body having a refractive index different from that of the matrix in the matrix, whereas a hole in the matrix is preferable as the area because it renders a larger difference in the refractive index from the matrix and is easier to manufacture.

In a photonic crystal, owing to the periodic structure, a band structure of photon energy is formed including an energy region or regions within which light cannot propagate, that is called “photonic bandgap”. The bandgap depends on the refractive index of the dielectric matrix and the periodic structure formed in it. In a two-dimensional photonic crystal, light having the wavelength falling within the bandgap cannot propagate along the slab body in which the periodic structure is formed, and can propagate perpendicular to the slab body. Thus, by providing a two-dimensional photonic crystal within an LED device, the light emitted from the active layer of the LED does not propagate along the two-dimensional photonic crystal but goes out solely perpendicular to it, which increases the luminous efficiency of the LED.

In Patent Document 1 shown below, an LED including a two-dimensional photonic crystal is disclosed, where the LED is composed of a p-type semiconductor cladding layer (“p-type doped layer” in Patent Document 1), an active layer and an n-type semiconductor cladding layer (“n-type doped layer”) are provided between a pair of electrodes, and air holes penetrating through the three layers are periodically arranged in the plane of the layers. In the LED, holes injected from the p-type semiconductor cladding layer and electrons injected from the n-type semiconductor cladding layer recombine in the active layer to generate light, wherein the generated light cannot propagate along the plane of the layers, and can be taken out in the direction perpendicular to the plane. This confers the high light emitting efficiency on the LED.

[Patent Document 1] Unexamined Japanese Patent Publication No. 2004-289096 ([0009]-[0010], [0015], [0020]-[0023], [0025], FIGS. 1 and 3) Generally, near a semiconductor surface, energy levels (“defect levels”) due to boundaries and lattice defects are generated in the energy levels of electrons. When electrons and holes combine in such a semiconductor surface area, the electrons and holes fall in the defect levels, so that heat instead of light is generated, which is called the “surface recombination”. Since the two-dimensional photonic crystal LED includes many air holes in the active layer, the surface area is larger than normal LEDs and the surface recombination occurs more frequently. The surface recombination deteriorates the light emitting efficiency and the energy efficiency of the LED.

In Patent Document 1, the surface recombination is suppressed by using materials comprising group III elements such as Gallium, Indium, Aluminum, etc. and Nitrogen which have slow surface recombination speed in the active layer.

### SUMMARY OF THE INVENTION

Thus an object of the present invention is to provide a two-dimensional photonic crystal LED less vulnerable to the surface recombination than conventional two-dimensional photonic crystal LEDs, and has a high light emitting efficiency and high energy efficiency.

According to the present invention, in an LED including a p-type semiconductor cladding layer, an active layer of light-emitting material and an n-type semiconductor cladding layer placed between a pair of electrodes, air holes penetrating through the layers are provided periodically, and at least a part of the inner wall of the air holes is oxidized in either one or both of the p-type semiconductor cladding layer and the n-type semiconductor cladding layer.

In the above structure of the LED, there may be other layers, such as a spacer layer, between the p-type semiconductor cladding layer and the active layer, or between the active layer and the n-type semiconductor cladding layer. The p-type semiconductor cladding layer, the active layer and the n-type semiconductor cladding layer can be made of the same material as conventional ones.

The p-type semiconductor cladding layer may be made of a single layer of the same material, or a stack of multiple layers of different materials. The same applies for the active layer and the n-type semiconductor cladding layer.

In one feature of the present invention, such a material that is more easily oxidized than the active layer is used for either one or both of the p-type semiconductor cladding layer and the n-type semiconductor cladding layer.

The p-type semiconductor cladding layer, the active layer of light-emitting material and the n-type semiconductor cladding layer in which air holes are provided periodically act as a two-dimensional photonic crystal. The air holes may penetrate through all the three layers, or they may be restricted within the p-type semiconductor cladding layer alone, or/and within the n-type semiconductor cladding layer alone. The air holes may be arranged in the rectangular lattice or in the triangular lattice as conventional two-dimensional photonic crystals, and the shape of each air hole may be cylindrical or other shape also as conventional ones.

The later-described effect of the present invention can be obtained by oxidizing the whole inner wall of the air holes of the p-type semiconductor cladding layer or of the n-type semiconductor cladding layer, and some effect can be obtained by oxidizing only a part of the inner wall of the air holes of the p-type semiconductor cladding layer or/and of the n-type semiconductor cladding layer. But, ultimately it is most preferable to oxidize the entire inner wall of the air holes of the p-type semiconductor cladding layer and the n-type semiconductor cladding layer.

The function and effect of the two-dimensional photonic crystal of the present invention is explained with reference to FIG. 1, which shows the vertical cross sectional view of an air hole penetrating through the p-type semiconductor cladding layer, the active layer and the n-type semiconductor cladding layer. When a voltage is applied between a pair of electrodes placed on the both sides of the three layers, hole are injected in the p-type semiconductor cladding layer 12 and electrons are injected in the n-type semiconductor cladding layer 13. Driven by the electric field produced by the pair of electrodes, the holes move in the p-type semiconductor cladding layer 12 and the electrons move in the n-type semiconductor cladding layer 13. Since at least a part of the inner wall of the air hole 16 is oxidized in the present invention, the holes and electrons avoid the oxidized part 17 having low conductivity and enter the active layer 11 through the border apart from the air hole 16. Thus, in the two-dimensional photonic crystal LED of the present invention, the surface recombination of the holes and electrons occur less than conventional ones having no oxidized part 17. This increases the light-generating recombination of holes and electrons and enhances the light-emitting efficiency of the LED. It also prevents heat generation and improves the energy efficiency.

It is preferred that the inner wall of the air hole in the active layer is not oxidized. When the inner wall of the air hole in the active layer is oxidized, a defect energy level or levels are generated, and recombination of holes and electrons producing heat rather than light are apt to occur. But, even when the inner wall of the air hole in the active layer is oxidized, the possibility of holes and electrons entering the oxidized region of the active layer decreases and the deleterious effect of recombination is minimized by providing oxidized regions in the p-type semiconductor cladding layer and in the n-type semiconductor cladding layer.

It is advantageous in manufacturing a two-dimensional photonic crystal device to use a material having larger tendency of oxidization than that of the active layer in at least a part of the p-type semiconductor cladding layer or of the n-type semiconductor cladding layer. For example, when materials easier to be oxidized are used for the p-type semiconductor cladding layer and the n-type semiconductor cladding layer, and a material harder to be oxidized is used for the active layer, the two cladding layers can be selectively oxidized by exposing the whole device to an oxidizing atmosphere. Another example is that a material having a certain degree of oxidization is used for the active layer, and materials having a larger oxidizing rate are used for the two cladding layers. In this case, by oxidizing the whole device in a very short time for the active layer to be oxidized, the inner wall of the air holes in the two cladding layers can be selectively oxidized.

For the well-oxidizable materials of the p-type semiconductor cladding layer and the n-type semiconductor cladding layer, semiconductor materials containing Al can be used, where AlGaAs, AlGaP, AlGaInP, AlGaN, etc. are examples. In this case, for the active layer, a material devoid of Al, such as GaAs, GaP, GaInP, GaN, etc. can be used. When these materials are used for the p-type semiconductor cladding layer, n-type semiconductor cladding layer and active layer, and the inner wall of the air holes are exposed to water vapor, the materials containing Al are easily oxidized, while the material of the active layer is not oxidized. Thus, the selective oxidization of the inner wall of the two cladding layers is facilitated.

Alternatively, for the active layer, a material having substantially the same composition as the well-oxidizable materials of the cladding layers but containing less Al compared to Ga. In this case, by controlling the length of time for which the inner wall of the air holes are exposed to water vapor, the inner wall in the cladding layers can be adequately oxidized while that in the active layer remains scarcely oxidized.

### BRIEF DESCRIPTION OF THE DRAWINGS

FIG. 1 is a vertical sectional view of an air hole of the two-dimensional photonic crystal LED according to an embodiment of the present invention.

FIG. 2A is a vertical sectional view of the two-dimensional photonic crystal LED according to an embodiment of the present invention, and FIG. 2B is the horizontal cross-sectional view on the plane A-A′.

FIGS. 3A-3E are vertical sectional views explaining the manufacturing method of the two-dimensional photonic crystal LED of the embodiment.

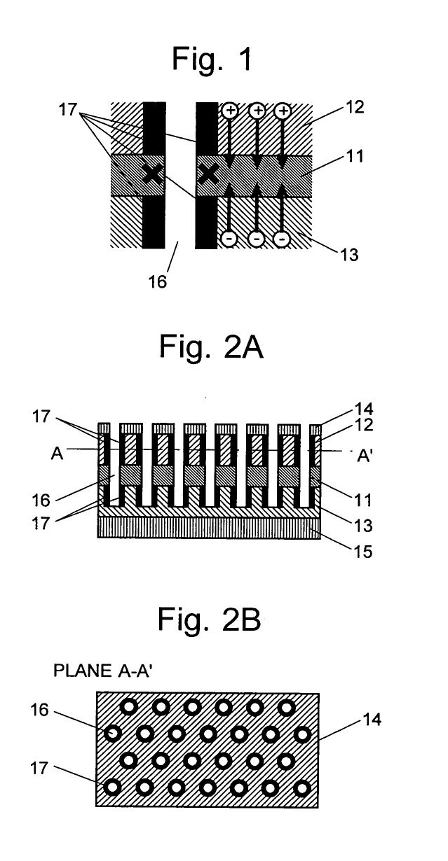

### DETAILED DESCRIPTION OF A PREFERRED EMBODIMENT

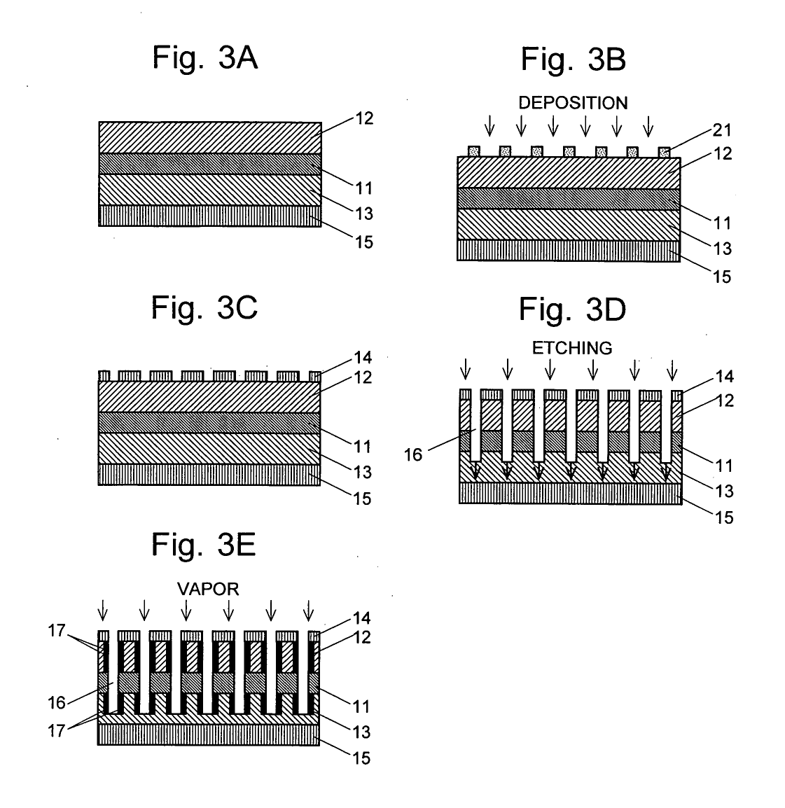

A two-dimensional photonic crystal LED embodying the present invention is explained referring to FIGS. 2 and 3. As shown in the cross sectional view of FIG. 2A, the two-dimensional photonic crystal LED of the present embodiment has the structure that an active layer 11 of GaAs/InGaAs is placed between a p-type semiconductor cladding layer 12 of p-type AlGaAs and n-type semiconductor cladding layer 13 of n-type AlGaAs, and the three layers are further placed between an upper electrode 14 of ITO and a lower electrode 15 of AuGeNi. For the upper electrode 14, besides ITO, any material that is transparent to the light generated in the device can be used. And for the lower electrode 15, besides AuGeNi, any material that reflects light generated in the device can be used. The p-type semiconductor cladding layer 12 may be composed of a stack of p-type AlGaAs layer and a p-type GaAs layer.

Through the p-type semiconductor cladding layer 12, the active layer 11 and the n-type semiconductor cladding layer 13, air holes 16 are provided substantially perpendicular to these layers. The air holes are formed so that they penetrate through the p-type semiconductor cladding layer 12 and the active layer 11, and stop within the n-type semiconductor cladding layer 13. As shown by the A-A′ cross-sectional view of FIG. 2B taken in the p-type semiconductor cladding layer 12, the air holes 16 are arranged on a two-dimensional triangular lattice in a plane parallel to these layers. The diameter of each air hole 16 is 0.1 μm, and the lattice constant of the triangular lattice is 0.35 μm. With this periodical arrangement of the air holes 16, a photonic band gap covering 0.98 μm wavelength of is formed. This means that light generated in the active layer having the wavelength of 0.98 μm cannot have the component that propagates in parallel to the plane of the three layers.

The air holes 16 can be formed so that they penetrate through the n-type semiconductor cladding layer 13 and the active layer 11, and stop within the p-type semiconductor cladding layer 12. Otherwise they may penetrate through all the three layers 12, 11, and 13.

Then, oxidized regions 17 are formed on the inner wall of the p-type semiconductor cladding layer 12 and the n-type semiconductor cladding layer 13. The oxidized regions 17 are made by oxidizing the material AlGaAs of the two layers 12 and 13. The thickness of the oxidized layers 17 is 0.05 μm in the present embodiment.

The operation of the two-dimensional photonic crystal LED of the present embodiment is as follows. When a voltage is applied between the upper electrode 14 and the lower electrode 15 with the upper electrode 14 positive, holes are ejected from the upper electrode 14 to the p-type semiconductor cladding layer 12, and electrons are ejected from the lower electrode 15 to the n-type semiconductor cladding layer 13. Since, in the semiconductor cladding layers 12 and 13, the conductivity of the oxidized regions 17 is lower than that of the other regions, the holes and electrons flow through the other regions and avoid the oxidized regions 17, i.e. the surface of the inner wall of the air holes 16. Then the holes and electrons are injected from the semiconductor cladding layers 12 and 13 to the active layer 11 and are combined to generate light in the place remote from the inner wall of the air holes 16. Thus, recombination near the surface of the inner wall of the air holes 16, i.e. the energy loss, is minimized, and the light emitting efficiency is maximized.

As described before, in the present embodiment, the light generated in the active layer 11 cannot propagate in parallel to the plane of the layers because the p-type semiconductor cladding layer 12 and the n-type semiconductor cladding layer 13 act as a two-dimensional photonic crystal with a band gap prohibiting the light, which forces the light only to propagate perpendicularly to the plane. The light emitted toward the lower electrode 15 is reflected by the lower electrode 15, so that the light generated in the active layer 11 is taken out from the upper electrode 14 at a high light emitting efficiency.

A method of manufacturing the two-dimensional photonic crystal LED of the present embodiment is described referring to FIGS. 3A-3E. First, using the lower electrode 15 of AuGeNi as the substrate, the n-type semiconductor cladding layer 13 of AlGaAs, the active layer 11 of GaAs/InGaAs and the p-type semiconductor cladding layer 12 of AlGaAs are successively formed on the substrate employing MOCVD or other depositing methods conventionally used (FIG. 3A). On the p-type semiconductor cladding layer 12, a mask layer 21 is formed where the areas corresponding to the air holes are masked (FIG. 3B). In forming the mask layer 12, the electron beam exposure method or the nano-imprinting method can be employed. Over the mask layer 21, the upper electrode layer 14 of ITO is formed, and the mask layer 21 is removed (FIG. 3C). Then the p-type semiconductor cladding layer 12, the active layer 11 and the n-type semiconductor cladding layer 13 are etched to form the deep air holes 16 penetrating through the three layers 12, 11 and 13 employing the reactive etching method, the inductive plasma etching or other high-aspect ratio selective etching method (FIG. 3D).

The inner wall of the air holes 16 is then exposed to a vapor of 400° C. for 60 seconds, whereby the surface of the inner wall of the air holes 16 in the p-type semiconductor cladding layer 12 and the n-type semiconductor cladding layer 13 is oxidized to a certain depth, forming the oxidized region 17 (FIG. 3E). Thus the two-dimensional photonic crystal LED of the present embodiment is manufactured.

What is claimed is:

1. A two-dimensional photonic crystal LED comprising:
a p-type semiconductor cladding layer, an active layer of light-emitting material, and an n-type semiconductor cladding layer placed between a pair of electrodes; and
air holes penetrating through the layers and arranged periodically in the layers,
wherein at least a part of an inner wall of the air holes is oxidized in either one or both of the p-type semiconductor cladding layer and the n-type semiconductor cladding layer.

2. The two-dimensional photonic crystal LED according to claim 1, wherein either one or both of the p-type semiconductor cladding layer and the n-type semiconductor cladding layer contain a well-oxidizable material which is easier to be oxidized than the active layer.

3. The two-dimensional photonic crystal LED according to claim 2, wherein the well-oxidizable material is AlGaAs, AlGaP, AlGaInP or AlGaN.

4. A method of manufacturing a two-dimensional photonic crystal LED comprising a p-type semiconductor cladding layer, an active layer of light-emitting material, and an n-type semiconductor cladding layer placed between a pair of electrodes, wherein the method comprises steps of:
forming air holes penetrating through the layers and arranged periodically in the layers; and
oxidizing at least a part of an inner wall of the air holes in either one or both of the p-type semiconductor cladding layer and the n-type semiconductor cladding layer.

5. The two-dimensional photonic crystal LED manufacturing method according to claim 4, wherein either one or both of the p-type semiconductor cladding layer and the n-type semiconductor cladding layer contain a well-oxidizable material which is easier to be oxidized than the active layer.

6. The two-dimensional photonic crystal LED manufacturing method according to claim 5, wherein the well-oxidizable material is AlGaAs, AlGaP, AlGaInP or AlGaN.
